(19) United States
(12) Patent Application Publication
(10) Pub. No.: US 2019/0115721 A1
(43) Pub. Date: Apr. 18, 2019

(54) LASER DIODE CONTROL CIRCUIT AND OPTICAL COMMUNICATION APPARATUS

(71) Applicant: FUJITSU LIMITED, Kawasaki-shi (JP)

(72) Inventors: Hirotomo Izumi, Kawasaki (JP); Shigeki Kawaai, Kawasaki (JP); Daisuke USUI, Kawasaki (JP); Yohei Miura, Kawasaki (JP)

(73) Assignee: FUJITSU LIMITED, Kawasaki-shi (JP)

(21) Appl. No.: 16/157,199

(22) Filed: Oct. 11, 2018

(30) Foreign Application Priority Data
Oct. 17, 2017 (JP) 2017-200962

(51) Int. Cl. H01S 5/0683; H01S 5/042; H01S 5/068

(52) U.S. Cl. CPC H01S 5/0683; H01S 5/06808; H01S 5/042

(57) ABSTRACT

A laser diode control circuit includes, a control signal supply circuit that supplies a control signal including a direct current component and an alternating current component to a laser diode, an optical output signal acquisition circuit that acquires an optical output signal indicating an optical output of the laser diode according to the control signal, a phase determination circuit that determines whether a phase of the alternating current component included in the optical output signal is the same as the phase of the alternating current component included in the control signal, and a control signal determination circuit that determines to decrease the direct current component of the control signal when it is determined that the phase of the alternating current component included in the optical output signal is not the same as the phase of the alternating current component included in the control signal.

### CROSS-REFERENCE TO RELATED APPLICATION

This application is based upon and claims the benefit of priority of the prior Japanese Patent Application No. 2017-200962, filed on Oct. 17, 2017, the entire contents of which are incorporated herein by reference.

### FIELD

The embodiments discussed herein are related to a laser diode control circuit and an optical communication apparatus.

### BACKGROUND

A technology is known in which a constant current bias and a sinusoidal current are superimposed with each other and the superimposed currents are applied to a semiconductor laser as a driving current, and a thermal characteristic of a semiconductor laser is measured based on a phase difference between the driving current and an optical output (see, e.g., Japanese Laid-open Patent Publication No. 61-110482). According to such a technology, it becomes possible that the thermal characteristic of the semiconductor laser can be easily and accurately measured.

Related technologies are disclosed in, for example, Japanese Laid-open Patent Publication No. 61-110482.

### SUMMARY

According to an aspect of the embodiments, a laser diode control circuit includes, a control signal supply circuit that supplies a control signal including a direct current component and an alternating current component to a laser diode, an optical output signal acquisition circuit that acquires an optical output signal indicating an optical output of the laser diode according to the control signal, a phase determination circuit that determines whether a phase of the alternating current component included in the optical output signal is the same as the phase of the alternating current component included in the control signal, and a control signal determination circuit that determines to decrease the direct current component of the control signal when it is determined that the phase of the alternating current component included in the optical output signal is not the same as the phase of the alternating current component included in the control signal.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1A is a diagram for describing an operation of a laser diode control circuit according to an embodiment;

FIG. 1B is a diagram illustrating an I-P characteristic of a laser diode;

FIG. 2A is a circuit block diagram of a light source including a laser diode control circuit according to a first embodiment;

FIG. 2B is a functional block diagram of the laser diode control circuit illustrated in FIG. 2A;

FIG. 3 is a flowchart of a laser diode control process executed by the laser diode control circuit illustrated in FIG. 2B;

FIG. 4 is a diagram for describing processes S103 and S104 illustrated in FIG. 3;

FIG. 5A is a circuit block diagram of a light source including a laser diode control circuit according to a second embodiment;

FIG. 5B is a functional block diagram of the laser diode control circuit illustrated in FIG. 5A;

FIG. 6 is a flowchart of a laser diode control process executed by the laser diode control circuit illustrated in FIG. 5B;

FIG. 7 is a diagram for describing processes S203 and S204 illustrated in FIG. 6;

FIG. 8A is a circuit block diagram of a light source including a laser diode control circuit according to a third embodiment;

FIG. 8B is a functional block diagram of the laser diode control circuit illustrated in FIG. 8A;

FIG. 9 is a flowchart of a laser diode control process executed by the laser diode control circuit illustrated in FIG. 8B;

FIG. 10 is a diagram for describing processes S303 and S304 illustrated in FIG. 9; and

FIG. 11 is a block diagram of an optical communication apparatus with a laser diode control circuit according to an embodiment.

### DESCRIPTION OF EMBODIMENTS

There is known a technology for controlling an optical output of a laser diode to be constant which is also referred to as an auto power control (APC). The APC utilizes an IP characteristic representing the relationship between an input current and an optical output, and the optical output is controlled by using a monotonically increasing region in which the optical output linearly and monotonically increases as the input current increases, thereby enabling a stable control.

However, when the laser diode is used under a high temperature and when the laser diode is used over a long period of time, there is a case where a kink region where a phenomenon of a nonlinear or nonmonotonous increase which is also called a kink occurs in the I-P characteristic may be shifted to a low current side. Further, as a manufacturing variation in the I-P characteristic increases with the miniaturization of the laser diode, there is a fear that the kink may occur at the low current side of the I-P characteristic. Since there is the fear that the kink may occur at the low current side of the I-P characteristic, it is not easy to control the laser diode by increasing the input current by the APC so as to increase the optical output.

Hereinafter, a laser diode control circuit and an optical communication apparatus according to embodiments will be described with reference to the accompanying drawings. However, the technical scope of the present disclosure is not limited to the embodiments.

(Operation of Related Laser Diode Control Circuit)

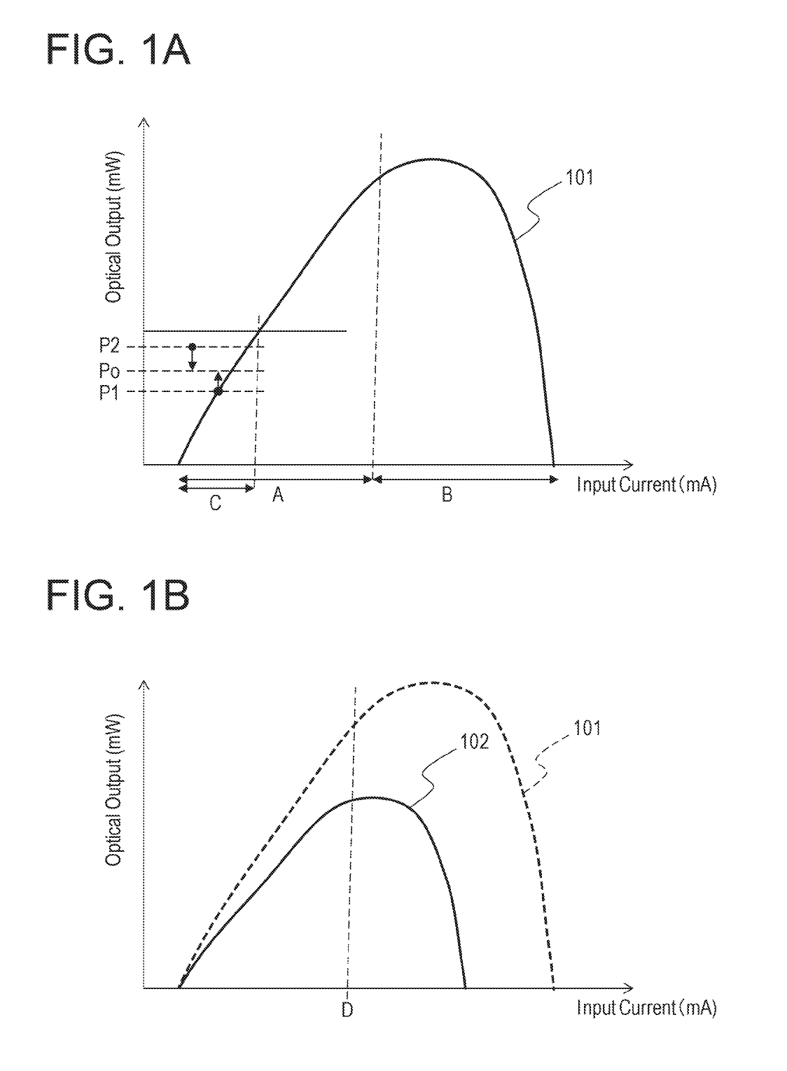

FIG. 1A is a diagram for describing an operation of a laser diode control circuit according to an embodiment, and FIG. 1B is a diagram illustrating an I-P characteristic of a laser diode. In FIGS. 1A and 1B, the horizontal axis represents the input current (mA) and the vertical axis represents the optical output (mW).

The control of the laser diode by the APC of the laser diode control circuit according to the embodiment will be described with reference to FIG. 1A. An I-P characteristic waveform 101 includes a monotonously increasing region A in which the optical output monotonously increases with the increase of the input current and a kink region B in which the relationship between the input current and the optical output nonlinearly and non-monotonously increases.

The relevant laser diode control circuit executes the APC control in an APC application region C included in the monotonously increasing region A of the I-P characteristic waveform 101. The relevant laser diode control circuit executes the APC control so that an optical output P of the laser diode coincides with a target value Po. The relevant laser diode control circuit increases the optical output P of the laser diode by increasing the input current by ΔI when the optical output P of the laser diode is P1 smaller than the target value Po. Meanwhile, the relevant laser diode control circuit decreases the optical output P of the laser diode by decreasing the input current by ΔI when the optical output P of the laser diode is P2 larger than the target value Po. Further, the relevant laser diode control circuit maintains the optical output P of the laser diode at a constant value without changing the input current when the optical output P of the laser diode is equal to the target value Po.

The relevant laser diode control circuit may control the laser diode so that the optical output P of the laser diode becomes the constant value Po, by executing the APC control in the APC application region C.

The I-P characteristic waveform 101 of the laser diode may fluctuate as in, for example, an I-P characteristic waveform 102, depending on, for example, a use state, a user period, and the manufacturing variation of the laser diode. The I-P characteristic waveform of the laser diode is shifted from the I-P characteristic waveform 101 to the I-P characteristic waveform 102 when the use temperature becomes high, when the use period becomes long so that the aged deterioration of the laser diode occurs, and when the characteristic is deteriorated due to the manufacturing variation. When the IP characteristic waveform is shifted from the IP characteristic waveform 101 to the IP characteristic waveform 102, the monotonously increasing region which is the usable region in the APC becomes narrow.

In the APC control by the relevant laser diode control circuit, since the IP characteristic of the laser diode may be shifted from the IP characteristic waveform 101 to the IP characteristic waveform 102, it is not easy to use a region in which the input current of the monotonously increasing region A is relatively high. For example, when the relevant laser diode control circuit executes the APC control such that the region including the input current indicated by a dashed line D in FIG. 1B is included in the APC application region C, the control becomes unstable when the I-P characteristic waveform is changed to the I-P characteristic waveform 102.

(Outline of Laser Diode Control Circuit According to Embodiment)

The laser diode control circuit according to the embodiment supplies a control signal including a direct current (DC) component and an alternating current (AC) component to the laser diode in order to determine whether the phase of the AC component included in the control signal is the same as the phase of an AC component included in an optical output signal. The laser diode control circuit according to the embodiment determines that the laser diode is controlled in the monotonously increasing region, when the phases of the AC components included in the control signal and the optical output signal are the same as each other. Meanwhile, the laser diode control circuit according to the embodiment determines that the laser diode is controlled in a region other than the monotonously increasing region, when the phases of the AC components included in the control signal and the optical output signal are not equal to each other. The laser diode control circuit according to the embodiment controls the input current supplied to the laser diode based on the phase relationship of the AC components included in the control signal and the optical output signal so as to control the laser diode widely in the monotonously increasing region where the kink does not occur.

(Configuration and Function of Light Source Including Laser Diode Control Circuit According to First Embodiment)

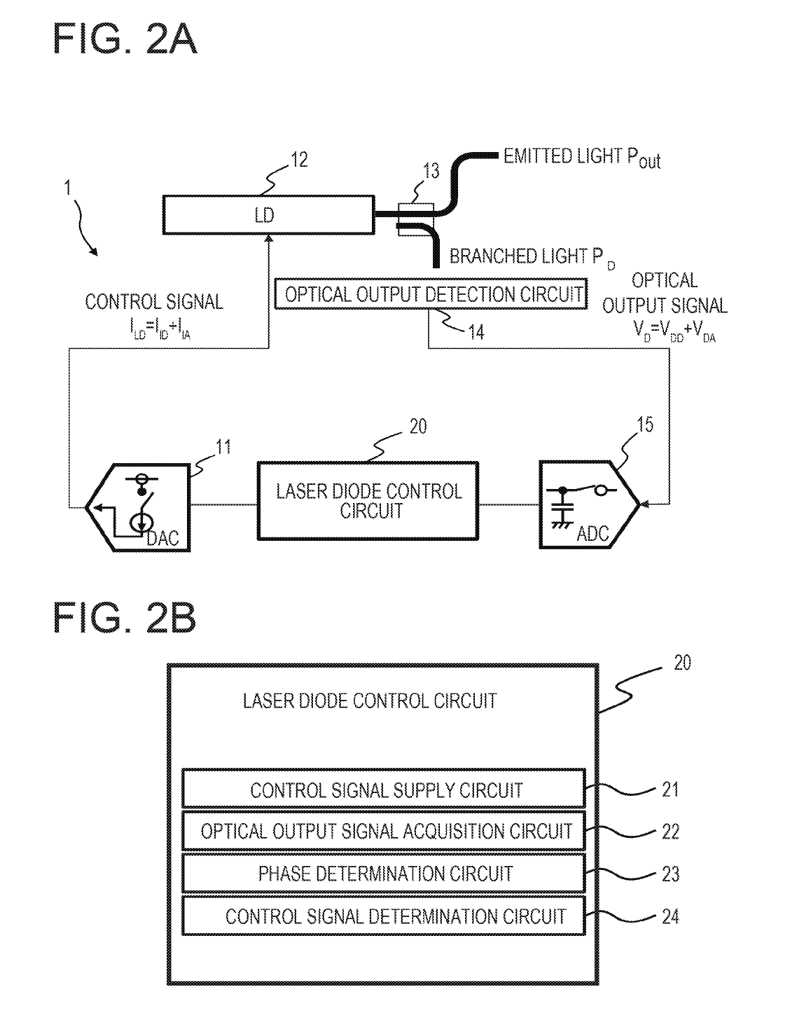

FIG. 2A is a circuit block diagram of a light source including a laser diode control circuit according to a first embodiment, and FIG. 2B is a functional block diagram of the laser diode control circuit illustrated in FIG. 2A.

A light source 1 includes a DA converter 11, a laser diode 12, an optical coupler 13, an optical output detection circuit 14, an AD converter 15, and a laser diode control circuit 20.

The DA converter 11 converts a control signal input from the laser diode control circuit 20 from a digital signal to an analog signal and outputs the analog signal to the laser diode 12. The control signal includes a DC component I_{ID} and an AC component I_{IA}. A frequency of the AC component I_{IA} of a control signal I_{LD} is, for example, less than 10 Hz, that is, approximately several Hz, and an amplitude of the AC component I_{IA} of the control signal I_{LD} is, for example, 1/100 or less, that is, 1% or less of the amplitude of the DC component I_{ID} of the control signal I_{LD}. Since the configuration and the function of the DA converter 11 are well known, a detailed description thereof will be omitted here.

The laser diode 12 emits light according to the control signal I_{LD} in which the DC component I_{ID} and the AC component I_{IA} are superimposed with each other. Since the configuration and the function of the laser diode 12 are well known, a detailed description thereof will be omitted here. Since the control signal I_{LD} includes the AC component I_{IA}, the laser diode 12 emits light including the AC component.

The optical coupler 13 is formed by an optical element such as an optical fiber and an optical waveguide, and branches a part of the light emitted from the laser diode 12 and makes the branched light be incident in the optical output detection circuit 14. Since the configuration and the function of the optical coupler 13 are well known, a detailed description thereof will be omitted here. For example, in a case of using an optical coupler designed with a branching ratio of 0.95:0.05, the optical coupler is disposed such that 95% of the light emitted from the laser diode 12 is set as main emission light Pₒᵤₜ, and 5% branched light PD is incident in the optical output detection circuit 14.

The optical output detection circuit 14 detects the optical output of the laser diode 12 and outputs an optical output signal V_{D} indicating the detected optical output. The optical output detection circuit 14 includes a photoelectric conversion element that flows a current depending on the optical output of the branched light P_{D} and a resistance element that converts the current supplied from the photoelectric conversion element into a voltage, and outputs the voltage depending on the branched light P_{D} associated with the optical output of the laser diode 12 as the optical output signal V_{D}. The photoelectric conversion element included in the optical output detection circuit 14 is, for example, a photo coupler. Since the light emitted from the laser diode 12 contains the AC component, the optical output signal V_{D} includes an AC component V_{DA} in addition to a DC component V_{DD}.

The AD converter 15 converts the optical output signal input from the optical output detection circuit 14 from the analog signal to the digital signal and outputs the digital signal to the laser diode control circuit 20. Since the configuration and the function of the AD converter 15 are well known, a detailed description thereof will be omitted here.

The laser diode control circuit 20 includes a control signal supply circuit 21, an optical output signal acquisition circuit 22, a phase determination circuit 23, and a control signal determination circuit 24. The respective circuits may be mounted as firmware on the laser diode control circuit 20 or may be functional modules implemented by programs executed by a processor included in the laser diode control circuit 20.

(Laser Diode Control Process by Laser Diode Control Circuit According to First Embodiment)

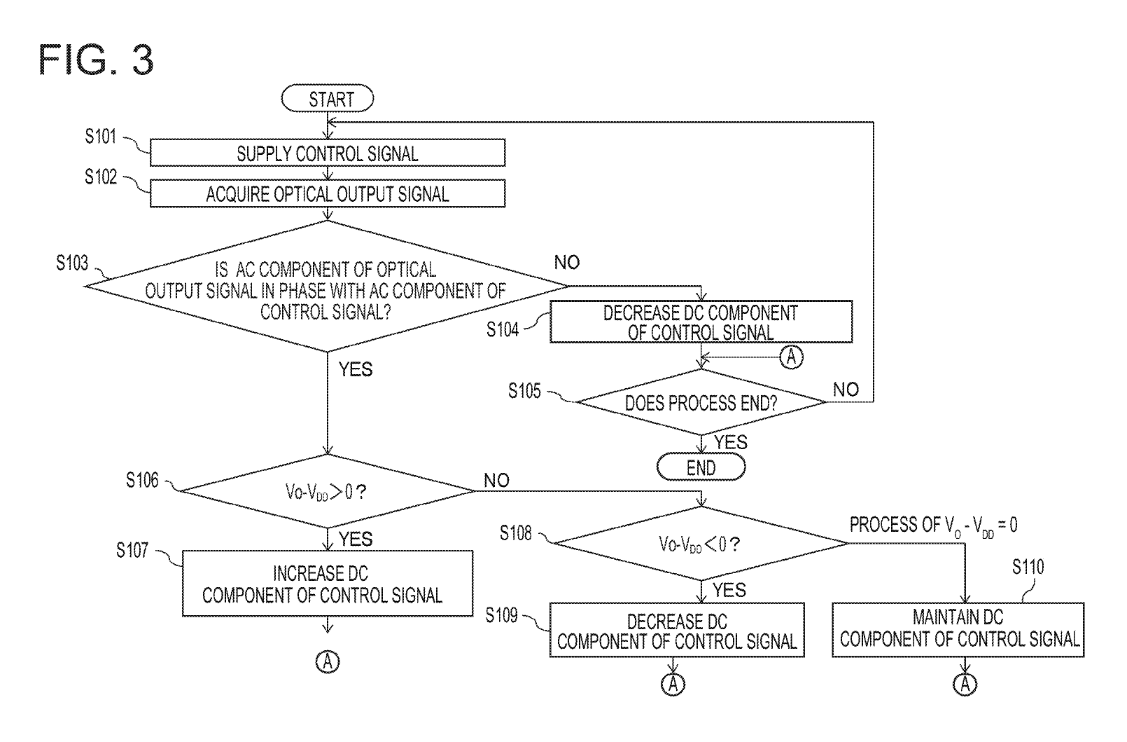

FIG. 3 is a flowchart of a laser diode control process executed by the laser diode control circuit 20. When each circuit of the laser diode control circuit 20 is a functional module, the laser diode control process illustrated in FIG. 3 is executed in cooperation with each element of the laser diode control circuit 20 based on a program stored in advance in a memory (not illustrated).

First, the control signal supply circuit 21 supplies the control signal I_{LD} including the DC component I_{ID} and the AC component I_{IA} to the laser diode 12 via the DA converter 11 (S101). Specifically, the control signal supply circuit 21 outputs a digital signal corresponding to the control signal I_{LD} where a bias value corresponding to an initial value of the DC component I_{ID} of the control signal I_{LD} and the AC component I_{IA} are superimposed with each other, to the DA converter 11.

Next, the optical output signal acquisition circuit 22 acquires the optical output signal V_{D} indicating the optical output of the laser diode 12 according to the control signal I_{LD} including the DC component I_{ID} and the AC component I_{IA} via the optical coupler 13 and the optical output detection circuit 14 (S102). Since the control signal I_{LD} includes the DC component I_{ID} and the AC component I_{IA}, the optical output of the laser diode 12 includes a DC component and an AC component, and the optical output signal V_{D} includes the DC component V_{DD} and the AC component V_{DA}.

Next, the phase determination circuit 23 determines whether the phase of the AC component V_{DA} included in the optical output signal V_{D} acquired in the process of S102 is the same as the phase of the AC component I_{IA} included in the control signal I_{LD} supplied in the process of S101 (S103). The phase determination circuit 23 estimates the phase of the AC component V_{DA} included in the optical output signal V_{D} from, for example, a temporal change of the AC component V_{DA} estimated from a digital value corresponding to the AC component V_{DA}. The phase determination circuit 23 estimates the phase of the AC component I_{IA} included in the control signal I_{LD} from the AC component of the digital signal corresponding to the control signal I_{LD}.

When it is determined that the AC component V_{DA} included in the optical output signal V_{D} is in phase with the AC component I_{IA} included in the control signal I_{LD} (“YES” in S103), the phase determination circuit 23 outputs the in-phase signal. Further, when it is determined that the AC component V_{DA} included in the optical output signal V_{D} is not in phase with the AC component I_{IA} included in the control signal I_{LD} (“NO” in S103), the phase determination circuit 23 outputs the non-in-phase signal to the control signal determination circuit 24.

When it is determined that the AC component V_{DA} included in the optical output signal V_{D} is not in phase with the AC component I_{IA} included in the control signal I_{LD} (“NO” in S103) and the non-in-phase signal is thus input, the control signal determination circuit 24 determines to decrease the DC component I_{ID} of the control signal I_{LD} (S104). An amount by which the control signal determination circuit 24 decreases the DC component I_{ID} of the control signal I_{LD} is a predetermined fixed value.

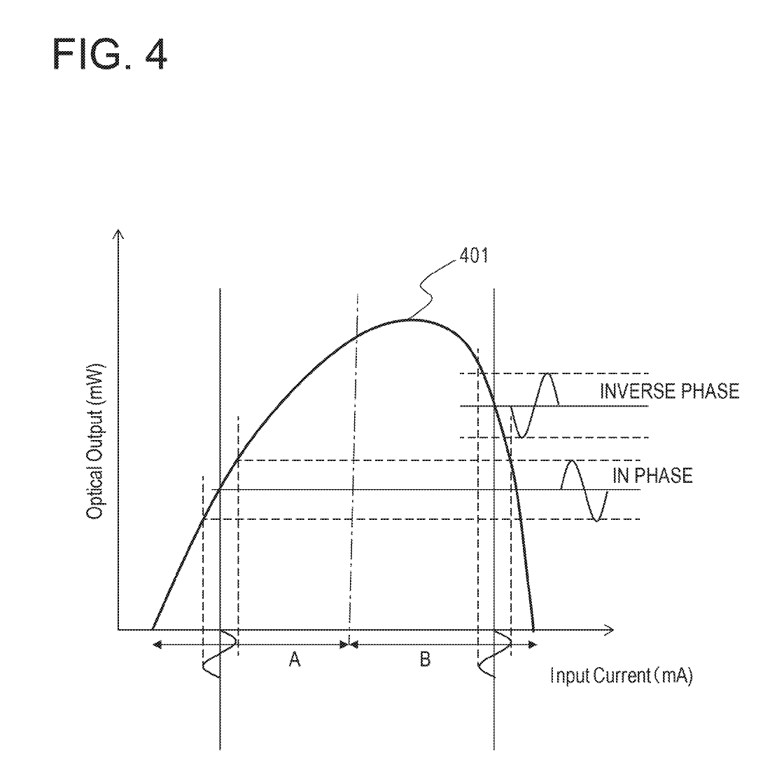

FIG. 4 is a diagram for describing processes S103 and S104. In FIG. 4, the horizontal axis represents the input current (mA) and the vertical axis represents the optical output (mW). An I-P characteristic waveform 401 includes a monotonously increasing region A in which the optical output monotonously increases with the increase of the input current, and a kink region B in which the relationship between the input current and the optical output nonlinearly and non-monotonously increases.

When the I-P characteristic waveform 401 is in the monotonously increasing region A, the optical output increases in accordance with the increase in the input current, so that the AC component V_{DA} included in the optical output signal V_{D} is in phase with the AC component I_{IA} included in the control signal I_{LD}. Meanwhile, when the I-P characteristic waveform 401 is in the non-monotonously increasing region B, the optical output decreases in accordance with the increase in the input current, so that the AC component V_{DA} included in the optical output signal V_{D} is not in phase with the AC component I_{IA} included in the control signal I_{LD}.

When it is determined that the AC component V_{DA} included in the optical output signal V_{D} is not in phase with the AC component I_{IA} included in the control signal I_{LD} (“NO” in S103), the control signal determination circuit 24 determines that the I-P characteristic waveform 401 is in the kink region B and decreases the DC component I_{ID}. When it is determined that the I-P characteristic waveform 401 is in the kink region B, the control signal determination circuit 24 decreases the DC component I_{ID} so as to move the I-P characteristic waveform 401 from the kink region B to the monotonically increasing region A.

Next, the control signal supply circuit 21 determines whether a control stop instruction signal indicating that the control process of the laser diode 12 is to be stopped is input from an upper control circuit (not illustrated) (S105). When the control signal supply circuit 21 determines that the control stop instruction signal is input (“YES” in S105), the process ends. Meanwhile, when the control signal supply circuit 21 determines that the control stop instruction signal is not input (“NO” in S105), the control signal supply circuit 21 outputs the control signal I_{LD} including the DC component I_{ID} and the AC component I_{IA} which decreased in process S104, to the laser diode 12 (S101).

When it is determined that the AC component V_{DA} of the optical output signal V_{D} is in phase with the AC component I_{IA} of the control signal I_{LD} (“YES” in S103), the control signal determination circuit 24 determines to increase/decrease or maintain the DC component I_{ID} of the control signal I_{LD} from a magnitude relationship of the DC component V_{DD} of the optical output signal V_{D} and a target value Vo (S106 and S108). That is, the control signal determination circuit 24 determines not only whether the DC component V_{DD} of the signal V_{D} is smaller than the target voltage Vo (S106) but also whether the DC component V_{DD} of the signal V_{D} is larger than the target voltage Vo (S108). The target voltage Vo is a voltage corresponding to a target optical output Po of the laser diode 12. For example, the control signal determination circuit 24 integrates the optical output signal V_{D} over a predetermined period, thereby removing the AC component V_{DA} from the optical output signal V_{D} and extracting the DC component V_{DD} included in the optical output signal V_{D}.

When it is determined that the DC component V_{DD} of the signal V_{D} is smaller than the target voltage Vo, that is, Vo−V_{DD}>0 (“YES” in S106), the control signal determination circuit 24 determines to increase the DC component I_{ID} of the control signal I_{LD} (S107). An amount by which the DC component I_{ID} of the control signal I_{LD} increases may be determined by a P_{ID} control, a PI control, or a P control. Next, the process proceeds to S105.

When it is determined that the DC component V_{DD} of the signal V_{D} is larger than the target voltage Vo, that is, Vo−V_{DD}<0 (“YES” in S108), the control signal determination circuit 24 determines to decrease the DC component I_{ID} of the control signal I_{LD} (S109). The control signal determination circuit 24 may determine an amount by which the DC component I_{ID} of the control signal I_{LD} decreases, by the P_{ID} control, the PI control, or the P control. Next, the process proceeds to S105.

When the control signal determination circuit 24 determines that the DC component V_{DD} of the signal V_{D} is equal to the target voltage Vo, that is, Vo−V_{DD}=0 (NO in S108), not Vo−V_{DD}>0 and Vo−V_{DD}<0, the control signal determination circuit 24 determines to maintain the DC component I_{ID} of the control signal I_{LD} at the same value (S110). Next, the process proceeds to S105.

Thereafter, processes S101 to S110 are repeated until it is determined that the control stop instruction signal is input by the control signal supply circuit 21 (“YES” in S105).

(Operational Effect of Laser Diode Control Circuit According to First Embodiment)

The laser diode control circuit according to the first embodiment prevents a control error due to the occurrence of kink by controlling the input current supplied to the laser diode based on the phase relationship of the AC components included in the control signal and the optical output signal. Further, by controlling the input current supplied to the laser diode based on the phase relationship of the AC components included in the control signal and the optical output signal, the laser diode control circuit may control the laser diode widely in the monotonously increasing region in which the kink does not occur. Since the laser diode control circuit according to the first embodiment may widely control the laser diode in the monotonously increasing region, the control error caused from the occurrence of kink may be prevented, and as a result, the optical output of the laser diode may be increased regardless of the variation in the occurrence of the kink.

(Configuration and Function of Light Source Including Laser Diode Control Circuit According to Second Embodiment)

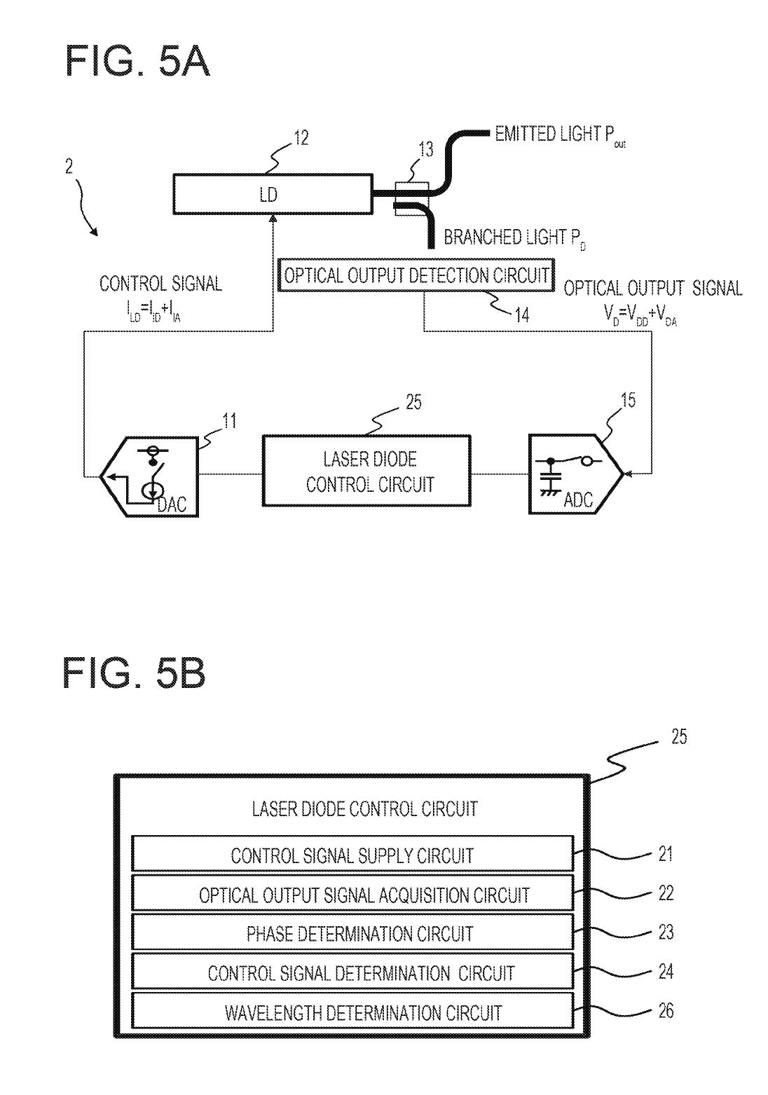

FIG. 5A is a circuit block diagram of a light source including a laser diode control circuit according to a second embodiment, and FIG. 5B is a functional block diagram of the laser diode control circuit illustrated in FIG. 5A.

A light source 2 is different from the light source 1 in that the light source 2 includes a laser diode control circuit 25, instead of the laser diode control circuit 20. Since the configurations and functions of the components of the light source 2 other than the laser diode control circuit 25 are the same as those of the components of the light source 1 denoted by the same reference numerals, the detailed description thereof will be omitted here. The laser diode control circuit 25 is different from the laser diode control circuit 20 in that the laser diode control circuit 25 includes a wavelength determination circuit 26.

(Laser Diode Control Process by Laser Diode Control Circuit According to Second Embodiment)

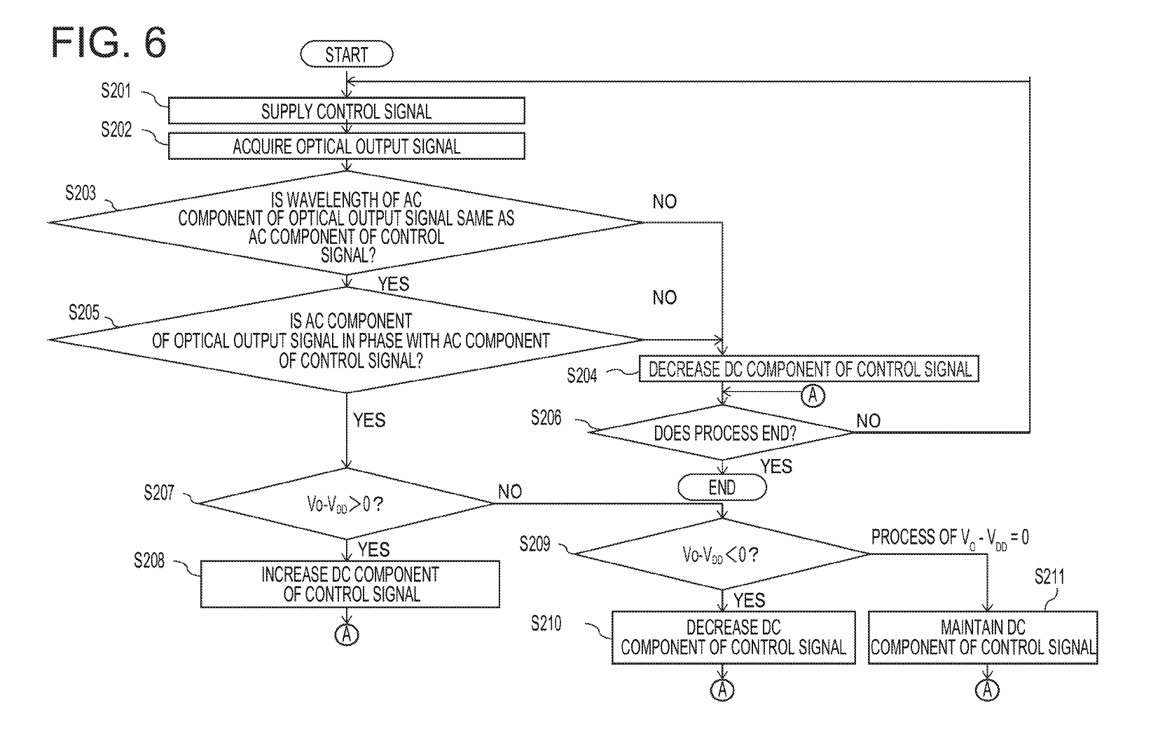

FIG. 6 is a flowchart of a laser diode control process executed by the laser diode control circuit 25. In the laser diode control process illustrated in FIG. 6, when each unit of the laser diode control circuit 25 is a functional module, the laser diode control process is executed in cooperation with each element of the laser diode control circuit 25 based on a program stored in advance in a memory (not illustrated).

Since processes S201 and S202 are the same as processes S101 and S102, respectively, the detailed description will be omitted here.

Next, the wavelength determination circuit 26 determines whether the wavelength of the AC component V_{IA} included in the optical output signal V_{D} acquired in process S202 is the same as the wavelength of the AC component I_{IA} included in the control signal I_{LD} supplied in process S201 (S203). The wavelength determination circuit 26 estimates the wavelength of the AC component V_{DA} included in the optical output signal V_{D} from a temporal change of the AC component V_{DA} estimated from, for example, a digital value corresponding to the AC component V_{DA}. The wavelength determination circuit 26 estimates the wavelength of the AC component I_{IA} included in the control signal I_{LD} from the AC component of the digital signal corresponding to the control signal I_{LD}.

When it is determined that the wavelength of the AC component V_{DA} included in the optical output signal V_{D} is the same as the wavelength of the AC component I_{IA} included in the control signal I_{LD} (“YES” in S203), the wavelength determination circuit 26 outputs a wavelength coincidence signal. Further, when it is determined that the wavelength of the AC component V_{DA} included in the optical output signal V_{D} is not the same as the wavelength of the AC component I_{IA} included in the control signal I_{LD} (“NO” in S203), the wavelength determination circuit 26 outputs a wavelength incoincidence signal to the control signal determination circuit 24.

When it is determined that the wavelength of the AC component V_{DA} of the optical output signal V_{D} is not the same as the wavelength of the AC component I_{IA} of the control signal I_{LD} (“NO” in S203) and the wavelength incoincidence signal is input, the control signal determination circuit 24 determines to decrease the DC component I_{ID} of the control signal I_{LD} (S204). An amount by which the control signal determination circuit 24 decreases the DC component I_{ID} of the control signal I_{LD} is a predetermined fixed value.

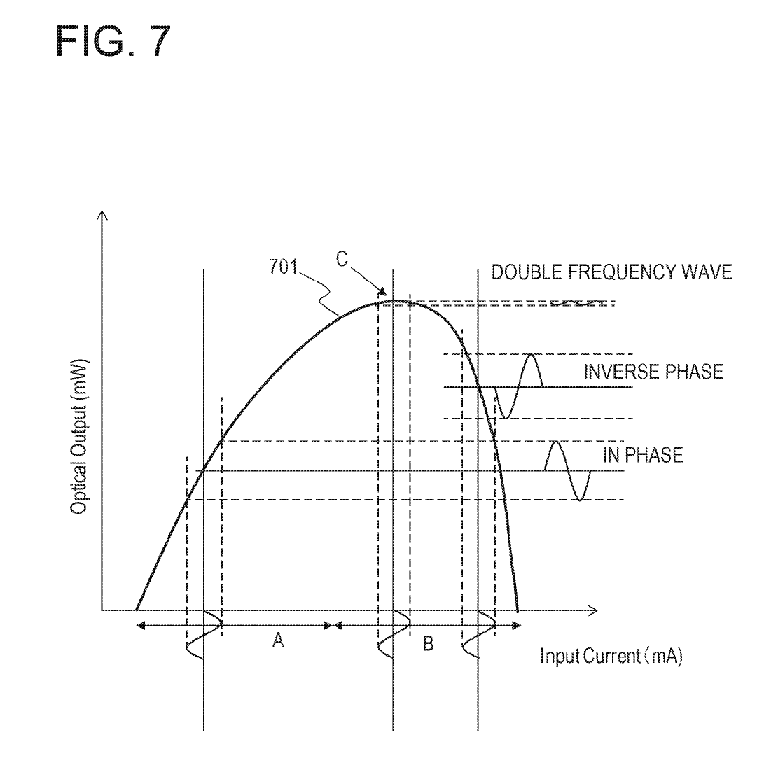

FIG. 7 is a diagram for describing processes S203 and S204. In FIG. 7, the horizontal axis represents the input current (mA) and the vertical axis represents the optical output (mW). An I-P characteristic waveform 701 includes a monotonously increasing region A in which the optical output monotonously increases in accordance with the increase in the input current, a kink region B in which the relationship between the input current and the optical output nonlinearly and non-monotonously increases, and a supersaturation region C near an apex of the I-P characteristic waveform 701.

When the I-P characteristic waveform 701 is near the supersaturation region C, the frequency of the AC component V_{DA} included in the optical output signal V_{D} becomes twice the frequency of the AC component I_{IA} included in the control signal I_{LD}. That is, when the I-P characteristic waveform 701 is near the supersaturation region C, the wavelength of the AC component V_{DA} included in the optical output signal V_{D} becomes half the wavelength of the AC component I_{IA} included in the control signal I_{LD}, and as a result, the wavelength of the AC component V_{DA} is different from the wavelength of the AC component I_{IA}.

When it is determined that the wavelength of the AC component V_{DA} included in the optical output signal V_{D} is not the same as the wavelength of the AC component I_{IA} included in the control signal I_{LD} (“NO” in S203), the control signal determination circuit 24 determines that the I-P characteristic waveform 401 is in the supersaturation region C of the I-P characteristic, and decreases the DC component I_{ID}. When it is determined that the I-P characteristic waveform 401 is in the supersaturation region C, the control signal determination circuit 24 decreases the DC component I_{ID} so as to move the I-P characteristic waveform 401 from the supersaturation region C to the monotonically increasing region A.

Since processes S205 to S211 are the same as processes S104 to S110, the detailed description will be omitted here.

(Operational Effect of Laser Diode Control Circuit According to Second Embodiment)

The laser diode control circuit according to the second embodiment decreases the DC component when the wavelength of the AC component of the optical output signal is not the same as the wavelength of the AC component of the control signal, and as a result, there is no possibility of controlling the laser diode in a region where the optical output monotonically decreases with the increase in the input current. The laser diode control circuit according to the second embodiment may control a higher input current as a control signal within a range in which there is no possibility that the laser diode is controlled in a region where the optical output monotonously decreases in accordance with the increase in the input current, so as to increase the optical output of the laser diode.

(Configuration and Function of Light Source Including Laser Diode Control Circuit According to Third Embodiment)

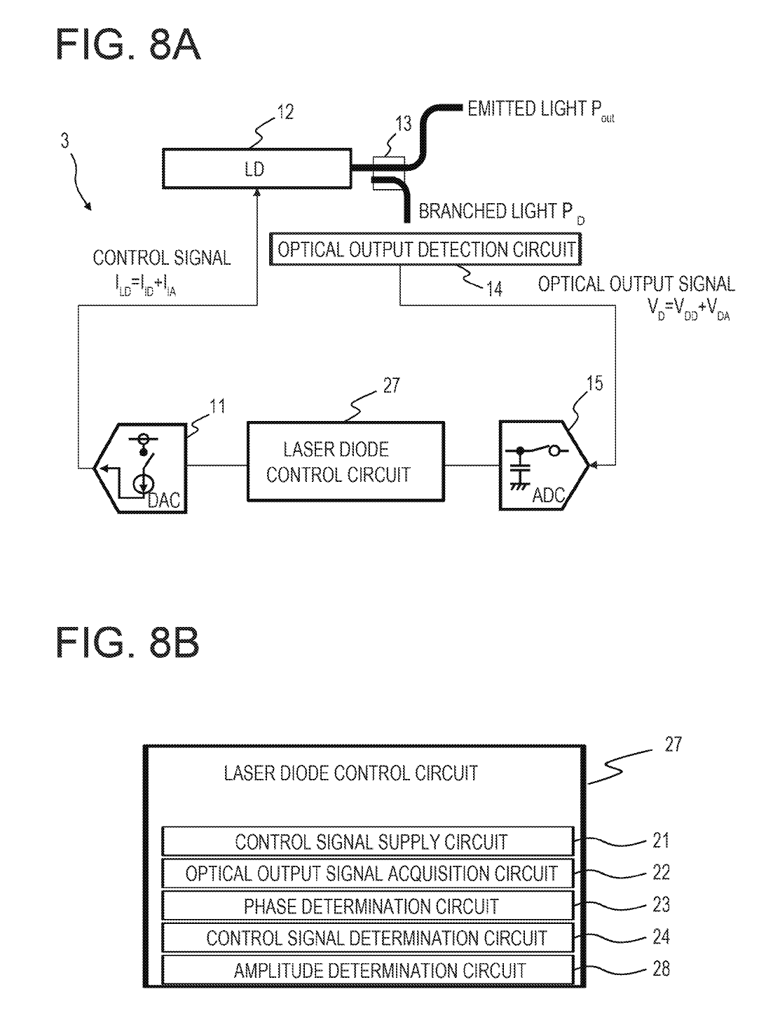

FIG. 8A is a circuit block diagram of a light source including a laser diode control circuit according to a third embodiment, and FIG. 8B is a functional block diagram of the laser diode control circuit illustrated in FIG. 8A.

A light source 3 is different from the light source 1 in that the light source 3 includes a laser diode control circuit 27, instead of the laser diode control circuit 20. Since the configurations and functions of the components of the light source 3 other than the laser diode control circuit 27 are the same as those of the components of the light source 1 denoted by the same reference numerals, the detailed description thereof will be omitted here. The laser diode control circuit 27 is different from the laser diode control circuit 20 in that the laser diode control circuit 27 includes an amplitude determination circuit 28.

(Laser Diode Control Process by Laser Diode Control Circuit According to Third Embodiment)

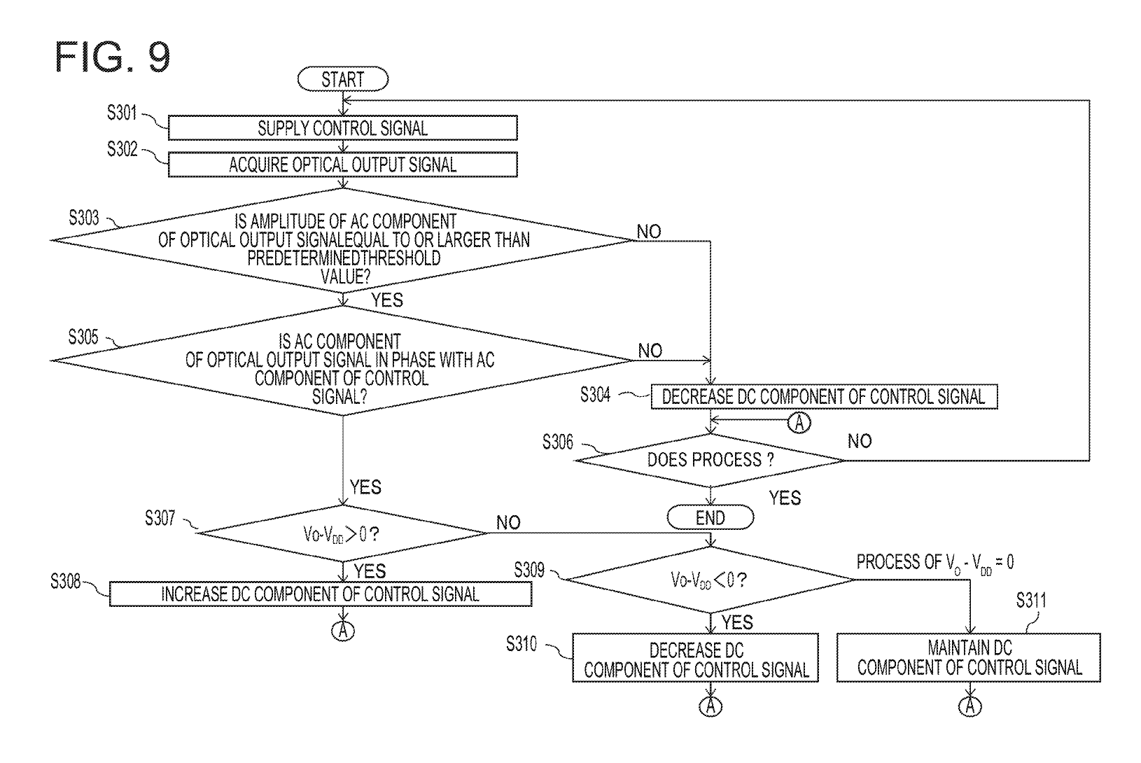

FIG. 9 is a flowchart of a laser diode control process executed by the laser diode control circuit 27. In the laser diode control process illustrated in FIG. 9, when each unit of the laser diode control circuit 27 is a functional module, the laser diode control process is executed in cooperation with each element of the laser diode control circuit 27 based on a program stored in advance in a memory (not illustrated).

Since processes S301 and S302 are the same as processes S101 and S102, the detailed description will be omitted here.

Next, an amplitude determination circuit 28 determines whether the amplitude of the AC component V_{DA} included in the optical output signal V_{D} obtained in process S302 is equal to or larger than a predetermined threshold value Vₜₕ (S303). The amplitude determination circuit 28 estimates the amplitude of the AC component V_{DA} included in the optical output signal V_{D} from, for example, a temporal change of the AC component V_{DA} estimated from a digital value corresponding to the AC component V_{DA}.

When it is determined that the amplitude of the AC component V_{DA} included in the optical output signal V_{D} is equal to or larger than the threshold value Vₜₕ (“YES” in S303), the amplitude determination circuit 28 outputs the large amplitude signal. Further, when it is determined that the amplitude of the AC component V_{DA} included in the optical output signal V_{D} is smaller than the threshold value Vₜₕ (“NO” in S303), the amplitude determination circuit 28 outputs the small amplitude signal to the control signal determination circuit 24.

When it is determined that the amplitude of the AC component V_{DA} of the optical output signal V_{D} is smaller than the threshold value Vₜₕ (“NO” in S303) and the small amplitude signal is thus input, the control signal determination circuit 24 determines to decrease the DC component I_{ID} of the control signal I_{LD} (S304). An amount by which the control signal determination circuit 24 decreases the DC component I_{ID} of the control signal I_{LD} is a predetermined fixed value.

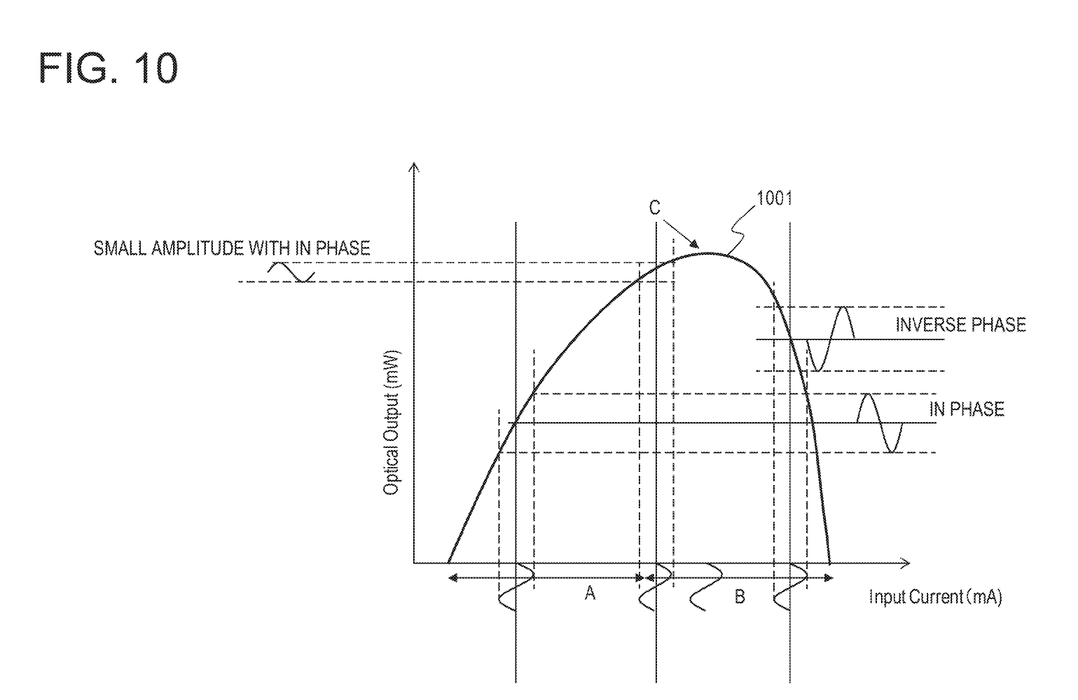

FIG. 10 is a diagram for describing processes S303 and S304. In FIG. 10, the horizontal axis represents the input current (mA), and the vertical axis represents the optical output (mW). An I-P characteristic waveform 1001 includes a monotonously increasing region A in which the optical output monotonously increases in accordance with the increase in the input current, a kink region B in which the relationship between the input current and the optical output nonlinearly and non-monotonously increases, and a supersaturation region C near an apex of the I-P characteristic waveform 701.

As the IP characteristic waveform 1001 approaches the supersaturation region C from the monotonously increasing region A, the inclination of the IP characteristic waveform 1001 gradually decreases. As the inclination of the IP characteristic waveform 1001 decreases, the amplitude of the AC component V_{DA} of the optical output signal V_{D} decreases.

When it is determined that the amplitude of the AC component V_{DA} included in the optical output signal V_{D} is smaller than the threshold value Vₜₕ (“NO” in S303), the control signal determination circuit 24 determines that the I-P characteristic waveform 401 is in the vicinity of the supersaturation region C of the I-P characteristic, and decreases the DC component I_{ID}. When it is determined that the I-P characteristic waveform 401 is in the vicinity of the supersaturation region C, the control signal determination circuit 24 decreases the DC component I_{ID} so as to move the I-P characteristic waveform 401 from the vicinity of the supersaturation region C to the monotonically increasing region A.

Since processes S305 to S311 are the same as processes S104 to S110, the detailed description will be omitted here.

(Operational Effect of Laser Diode Control Circuit According to Third Embodiment)

The laser diode control circuit according to the third embodiment decreases the DC component when the amplitude of the AC component of the optical output signal is smaller than a threshold value, and as a result, there is no fear of controlling the laser diode in the region in which the optical output monotonously decreases with the increase in the input current. The laser diode control circuit according to the third embodiment controls a higher input current as a control signal within a range in which there is no risk of the laser diode being controlled in a region where the optical output monotonously decreases in accordance with the increase in the input current, so as to increase the optical output of the laser diode.

(Modification of Light Source According to Embodiment)

In the light sources 1 to 3, the AC component of the control signal has a sinusoidal waveform, but in a light source according to an embodiment, the AC component of the control signal may be a triangular wave or a rectangular wave having a predetermined cycle.

(Application Example of Light Source According to Embodiment)

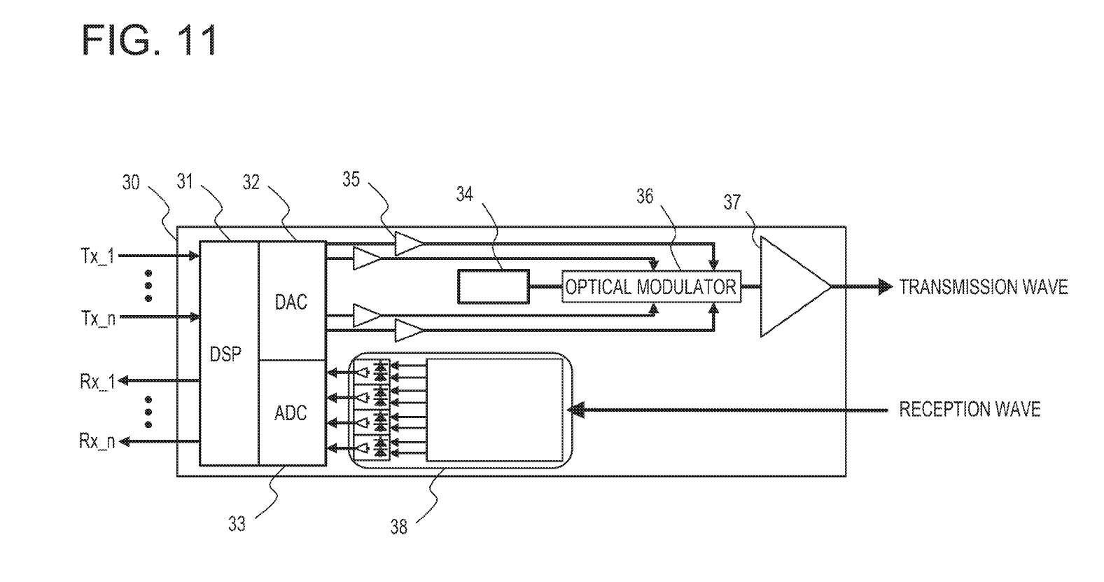

FIG. 11 is a block diagram of an optical communication apparatus with a laser diode control circuit according to an embodiment.

An optical communication apparatus 30 includes a digital signal processor (DSP) 31, a digital-to-analog converter 32, and an analog-to-digital converter 33. The optical communication apparatus 30 further includes a light source 34, a modulation driver 35, an optical modulator 36, an amplifier 37, and a reception front end 38.

Digital transmission signals Tx1 to Tx_n are input to the DSP 31. The DSP 31 executes predetermined processing on data corresponding to the input digital transmission signals Tx1 to Tx_n, and outputs a digital transmission signal indicating the data on which the predetermined processing has been executed, to the digital-to-analog converter 32. Further, a digital reception signal is input into the DSP 31 from the analog-to-digital converter 33, and the DSP 31 executes predetermined processing on data corresponding to the input digital reception signal and outputs digital reception signals Rx1 to Rx_n indicating the data on which the predetermined processing has been executed. In addition, the DSP 31 may calculate an error rate indicating a ratio of an occurrence of an error in a signal corresponding to the reception light from the digital reception signals Rx1 to Rx_n and calculate an error count indicating the number of times the error occurs in the signal corresponding to the reception light. The digital-to-analog converter 32 converts the digital transmission signal input from the DSP 31 to generate an analog transmission signal, and outputs the generated analog transmission signal to the modulation driver 35. The analog-to-digital converter 33 analog-to-digital converts the analog reception signal input from the reception front end 38, generates the digital transmission signal, and outputs the generated digital transmission signal to the DSP 31.

The light source 34 is any one of the light sources 1 to 3 according to the embodiment. The modulation driver 35 outputs the analog transmission signal input from the digital-to-analog converter 32 to the optical modulator 36. The optical modulator 36 outputs modulation light obtained by modulating the light output from the light source 34 to the EDFA 37 based on the analog transmission signal input via the modulation driver 35. The optical modulator 36 generates the modulation light by, for example, dual polarization-quadrature phase shift keying (DP-QPSK) of light. The amplifier 37 is, for example, an erbium doped fiber amplifier (EDFA), amplifies the light input from the optical modulator 36, and outputs the amplified light as transmission light. The reception front end 38 demodulates the reception light, photoelectrically converts the demodulated reception light, and outputs the light to the analog-to-digital converter 33.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A laser diode control circuit comprising:
a control signal supply circuit configured to supply a control signal including a direct current component and an alternating current component to a laser diode;
an optical output signal acquisition circuit configured to acquire an optical output signal indicating an optical output of the laser diode according to the control signal;
a phase determination circuit configured to determine whether a phase of the alternating current component included in the optical output signal is the same as the phase of the alternating current component included in the control signal; and
a control signal determination circuit configured to determine to decrease the direct current component of the control signal when it is determined that the phase of the alternating current component included in the optical output signal is not the same as the phase of the alternating current component included in the control signal.

2. The laser diode control circuit according to claim 1, further comprising:
a wavelength determination circuit configured to determine whether a wavelength of the alternating current component included in the optical output signal is the same as the wavelength of the alternating current component included in the control signal; and
the control signal determination circuit configured to determine to decrease the direct current component of the control signal when it is determined that the wavelength of the alternating current component included in the control signal is not the same as the wavelength of the alternating current component included in the optical output signal.

3. The laser diode control circuit according to claim 1, further comprising:
an amplitude determination circuit configured to determine whether an amplitude of the alternating current component included in the optical output signal is equal to or larger than a predetermined threshold value; and
the control signal determination circuit configured to determine to decrease the direct current component of the control signal when it is determined that the amplitude of the alternating current component included in the control signal is smaller than the threshold value.

4. An optical communication apparatus comprising:
a light source including:
a laser diode configured to emit light according to a control signal,
an optical output detection circuit configured to detect an optical output of the laser diode and output an optical output signal indicating detected optical output, and
a laser diode control circuit configured to receive the optical output signal and output the control signal according to the received optical output signal to the laser diode, the laser diode control circuit including:
a control signal supply circuit configured to supply a control signal including a direct current component and an alternating current component to the laser diode,
an optical output signal acquisition circuit configured to acquire an optical output signal indicating the optical output of the laser diode according to the control signal,
a phase determination circuit configured to determine whether a phase of the alternating current component included in the optical output signal is the same as the phase of the alternating current component included in the control signal, and
a control signal determination circuit configured to determine to decrease the direct current component of the control signal when it is determined that the phase of the alternating current component included in the optical output signal is not the same as the phase of the alternating current component included in the control signal;
a modulator configured to modulate light emitted from the light source in accordance with a modulation signal and output modulated light as a transmission light; and
a control circuit configured to output the modulation signal.

5. The optical communication apparatus according to claim 4,
wherein the laser diode control circuit further includes a wavelength determination circuit that determines whether a wavelength of the alternating current component included in the optical output signal is the same as the wavelength of the alternating current component included in the control signal, and
the control signal determination circuit is configured to determine to decrease the direct current component of the control signal when it is determined that the wavelength of the alternating current component included in the control signal is not the same as the wavelength of the alternating current component included in the optical output signal.

6. The optical communication apparatus according to claim 4,
wherein the laser diode control circuit further includes an amplitude determination circuit that determines whether an amplitude of the alternating current component included in the optical output signal is equal to or larger than a predetermined threshold value, and
the control signal determination circuit is configured to determine to decrease the direct current component of the control signal when it is determined that the amplitude of the alternating current component included in the control signal is smaller than the threshold value.
